(19) United States
(12) Patent Application Publication
(10) Pub. No.: US 2026/0231578 A1
(43) Pub. Date: Aug. 6, 2026

(54) HYBRID BONDING-BASED MICRO-LED CHIP AND METHOD FOR FORMING THE SAME

(71) Applicant: Hue Inc., Shanghai (CN)

(72) Inventor: Feng Feng, Shanghai (CN)

(73) Assignee: Hue Inc., Shanghai (CN)

(21) Appl. No.: 19/458,952

(22) Filed: Jan. 26, 2026

(30) Foreign Application Priority Data
Jan. 26, 2025 (CN) 202510124088.6

(51) Int. Cl. H10H 29/39; H10H 29/01; H10H 29/32; H10H 29/45; H10W 46/00; H10W 90/00; H10H 29/80; H10H 29/855

(52) U.S. Cl. CPC H10H 29/39; H10H 29/012; H10H 29/32; H10H 29/45; H10W 46/301; H10W 90/792; H10H 29/8321; H10H 29/855

(57) ABSTRACT

The present disclosure relates to a hybrid bonding-based micro-LED chip, including: an upper stacked layer, which includes: a first insulating layer configured to accommodate a light-emitting mesa and a first through-hole contact portion; a light-emitting mesa configured to emit light, wherein the top surface area of the light-emitting mesa is greater than the bottom surface area of the light-emitting mesa; and a first through-hole contact portion electrically connected with the bottom of the light-emitting mesa and passing through the first insulating layer; and a lower stacked layer, which includes: a second insulating layer configured to accommodate a second through-hole contact portion; a second through-hole contact portion passing through the second insulating layer; and a drive backplane electrically connected with the second through-hole contact portion, wherein the lower stacked layer is bonded with the upper stacked layer through hybrid bonding.

### CROSS-REFERENCE TO RELATED APPLICATION

This application claims the priority benefit of Chinese patent application No. 202510124088.6, filed on January 26, 2025. The entirety of the above-mentioned patent application is hereby incorporated by reference herein and made a part of this specification.

### BACKGROUND

### Technical Field

The present disclosure generally relates to the field of semiconductor, and more specifically relates to a hybrid bonding-based micro-LED chip. Furthermore, the present disclosure also relates to a method for manufacturing such a micro-LED chip.

### Description of Related Art

Micro light-emitting diode (Micro-LED) is a new type LED structure obtained by thin-filming, miniaturizing, and arraying the original LED structure, which integrates the arrayed micro level micro-LEDs on an active addressing drive panel to achieve the lighting and individual control of the micro-LEDs, thereby outputting the desired display image. The core structure of the micro-LED is a PN junction diode composed of direct-bandgap semiconductor material. When the upper and lower electrodes apply a forward bias voltage to the micro-LED to allow current to pass through, electrons and holes recombine in the active area, and meanwhile emit monochromatic light photons.

The light-emitting mesa is a micro-LED, which includes semiconductor materials of different conductivity types. For example, the common P-type semiconductor layer and N-type semiconductor layer have a light-emitting layer between the two layers. Taking a gallium nitride (GaN)-based micro-LED as an example, the N-type semiconductor layer typically uses N-type doped GaN, while the P-type semiconductor layer is P-type doped GaN, and the light-emitting layer is mostly an InGaN quantum well structure. When current passes through, electrons and holes recombine in the light-emitting layer, so that photons emitting light are generated.

Currently, there are generally two types of structures for light-emitting mesa, i.e., the light-emitting mesa is either exposed outside the insulating layer or accommodated in the insulating layer. When the light-emitting mesa is accommodated in the insulation layer, it can provide better protection and insulation for the light-emitting mesa. However, the process difficulty of this embedded structure lies in the limitation of existing processes, and it is difficult to achieve the upside-down arranged trapezoidal structure of the light-emitting mesa, while manufacturing IC copper pillars at the bottom of the light-emitting mesa.

### SUMMARY

Starting from the prior art, the task of the present disclosure is to provide a hybrid bonding-based micro-LED chip and a method for forming the same, through the micro-LED chip and the method, an upside-down arranged trapezoidal structure for the light-emitting mesa can be achieved, meanwhile, through-hole contact portions, such as IC copper pillars are also manufactured at the bottom of the light-emitting mesa.

In a first aspect of the present disclosure, the aforementioned task is solved by a hybrid bonding-based micro-LED chip, which includes:

an upper stacked layer comprising a first insulating layer, a light-emitting mesa and first through-hole contact portion, where the first insulating layer is configured to accommodate the light-emitting mesa and the first through-hole contact portion, the light-emitting mesa is configured to emit light, and the first through-hole contact portion is electrically connected with a bottom of the light-emitting mesa and configured to pass through the first insulating layer; and

a lower stacked layer comprising a second insulating layer, a second through-hole contact portion, and a drive backplane, where the second insulating layer is configured to accommodate the second through-hole contact portion; the second through-hole contact portion is configured to pass through the second insulating layer; and the drive backplane is electrically connected with the second through-hole contact,

where a top surface area of the light-emitting mesa is greater than a bottom surface area of the light-emitting mesa;

where the lower stacked layer is bonded with the upper stacked layer through hybrid bonding, so that the first through-hole contact is bonded with the second through-hole contact portion and the first insulating layer is bonded with the second insulating layer.

In one embodiment of the present disclosure, it is provided that:

the upper stacked layer further includes a first bonding mark, which is arranged in the first insulating layer and exposes a first marking surface;

the lower stacked layer further includes a second bonding mark, which is arranged in the second insulating layer and exposes a second marking surface; and

where during hybrid bonding, the first marking surface is aligned with the second marking surface to align the upper stacked layer with the lower stacked layer.

In another embodiment of the present disclosure, the light-emitting mesa comprises a first epitaxial layer, a light-emitting layer and a second epitaxial layer, where:

the first epitaxial layer is configured to extend beyond a recess of the first insulating layer and be in electrical contact with the light-emitting layer;

the light-emitting layer is located in the recess and between the first epitaxial layer and the second epitaxial layer; and

the second epitaxial layer is located in the recess and is in electrical contact with the light-emitting layer and the first through-hole contact portion.

In another embodiment of the present disclosure, the upper stacked layer further comprises a transparent conductive layer, a passivation layer, a cathode and an anode, where

the transparent conductive layer is located on the first epitaxial layer and is configured to electrically connect a cathode with the first epitaxial layer;

the passivation layer is configured to surround a side surface of the light-emitting mesa and extend to an upper surface of the first insulating layer;

the cathode is configured to surround the light-emitting mesa; and

the anode is configured to electrically connect with the drive backplane through a third through-hole contact portion passing through the first insulating layer and the second insulating layer.

In another embodiment of the present disclosure, the cathode includes:

an edge cathode located between the anode and the outermost light-emitting mesa, where a part of the edge cathode is on the passivation layer and another part is on the transparent conductive layer; and

a central cathode located between adjacent light-emitting mesas, where the central cathode is on the transparent conductive layer.

In another embodiment of the present disclosure, the cathode is a reflective electrode made of metal.

In another embodiment of the present disclosure, it is provided that:

a side of the edge cathode facing the light-emitting mesa is an inclined surface; and

two sides of the central cathode facing the light-emitting mesa are inclined surfaces.

In another embodiment of the present disclosure, the first epitaxial layer partially passes through the edge cathode and fully passes through the central cathode, where the an edge of the first epitaxial layer in the edge cathode is an inclined surface.

In another embodiment of the present disclosure, the upper stacked layer further includes:

a reflective mirror layer located between an inner wall of the recess and the passivation layer, where a side of the reflective mirror layer facing the light-emitting mesa has an inclined surface to reflect light from the light-emitting mesa upward.

In another embodiment of the present disclosure, the upper stacked layer further includes a microlens, the microlens includes:

a lens portion located at an outermost and configured to shape light from the light-emitting mesa; and

a spacer portion located between the lens portion and the light-emitting mesa to adjust the focal position of the lens portion.

In another embodiment of the present disclosure, the first through-hole contact portion has a first aperture at a surface of the first insulating layer, where an interface metal layer is arranged at the first aperture, and an area of the interface metal layer is larger than an area of the first aperture; and/or

the second through-hole contact portion has a second aperture at a surface of the second insulating layer, where an interface metal layer is arranged at the second aperture, and the area of the interface metal layer is larger than an area of the second aperture.

In another embodiment of the present disclosure, the passivation layer is provided between the reflective mirror layer and the inner wall of the recess.

In another embodiment of the present disclosure, the first epitaxial layers of adjacent light-emitting mesas pass through the central cathode and are continuous with each other.

In another embodiment of the present disclosure, the first through-hole contact portion and the second through-hole contact portion are IC copper pillars, a surface of the drive backplane has a metal layer, the IC copper pillars are electrically connected with the metal layer, and each light-emitting mesa corresponds to one IC copper pillar.

In another embodiment of the present disclosure, the passivation layer is a SiO₂ film, or an Al₂O₃ film, or a SiO₂/Al₂O₃ composite structure film.

In another embodiment of the present disclosure, it is provided that:

a thickness of the first insulating layer is 0.6 to 1.4 μm; and/or

a thickness of the second insulating layer is 0.6 to 1.4 μm.

In another embodiment of the present disclosure, it is provided that:

a diameter of the first through-hole contact portion is 0.6 to 1.4 μm; and/or

a diameter of the second through-hole contact portion is 0.8 to 1.6 μm.

In another embodiment of the present disclosure, it is provided that:

a thickness of the passivation layer between the reflective mirror layer and the light-emitting mesa is 1000 to 1600 angstroms; and/or

a thickness of the passivation layer between the reflective mirror layer and the inner wall of the recess is 300 to 600 angstroms; and/or

a material of the reflective mirror layer includes silver and its thickness is 3000 to 3500 angstroms.

In another embodiment of the present disclosure, it is provided that:

a top width of the light-emitting mesa is 1.0 to 2.0 μm; and/or

a thickness of the first epitaxial layer is 4000 to 5000 angstroms; and/or

a thickness of the light-emitting layer is 3500 to 4000 angstroms; and/or

a thickness of the second epitaxial layer is 2500 to 3500 angstroms.

In another embodiment of the present disclosure, it is provided that:

a width of the microlens is 1 to 3 μm; and/or

a distance between the lens portion and the cathode is 0.1 to 0.3 μm.

In a second aspect of the present disclosure, the aforementioned task is solved by a method for manufacturing a micro-LED chip, the method includes the following steps:

forming a part of an upper stacked layer on a temporary substrate, including:

depositing an emitting layer and a second epitaxial layer of a light-emitting mesa on the temporary substrate;

depositing a passivation layer on the light-emitting mesa;

depositing a first insulating layer on the light-emitting mesa;

etching a first through-hole contact portion on the first insulating layer, where a bottom of the first through-hole contact portion exposes a bottom of the light-emitting mesa;

depositing metal in the first through-hole contact portion; and

debonding the upper stacked layer from the temporary substrate;

forming a lower stacked layer, including:

forming a drive backplane;

depositing a second insulating layer on the drive backplane;

etching a second through-hole contact portion on the second insulating layer, where a bottom of the second through-hole contact portion exposes an electrical contact portion of the drive backplane; and

depositing metal in the second through-hole contact portion; and

hybrid bonding the upper stacked layer and the lower stacked layer, so that the first through-hole contact portion is bonded with the second through-hole contact portion and the first insulating layer is bonded with the second insulating layer.

In one embodiment of the present disclosure, the method further includes the following steps:

depositing a passivation layer on the top surface of the light-emitting mesa and the first insulating layer;

etching the passivation layer to expose the light-emitting layer of the light-emitting mesa;

depositing a first epitaxial layer on the light-emitting layer;

depositing a transparent conductive layer on the first epitaxial layer;

depositing a cathode on the transparent conductive layer;

depositing microlenses on the cathode and the transparent conductive layer;

etching the first and second insulating layers at the side surface of the light-emitting mesa to form a third through-hole contact portion, and the bottom of the third through-hole contact portion exposes an electrical contact portion of the drive backplane; and

depositing metal in the third through-hole contact portion to form an anode.

The present disclosure has at least the following beneficial effects:

(1) The present disclosure solves the technical problem encountered in manufacturing upside-down arranged trapezoidal light-emitting mesa with a large upper surface and a small lower surface, i.e., the problem of electrical connection of the light-emitting mesa to the driving circuit, by respectively fabricating the upper stacked layer and the lower stacked layer and then jointing them with each other through hybrid bonding. The present disclosure achieves electrical connection of the light-emitting mesa to the drive backplane through hybrid bonding, allowing both the upper stacked layer and the lower stacked layer to be manufactured from the surface opposed to the hybrid bonding surface toward the hybrid bonding surface, so that high-quality conductive structures, such as the through-hole contact portions (such as IC copper pillars) are achieved, and the length of the conductive structure can also be flexibly selected.

(2) In the present disclosure, by protruding the first epitaxial layer at the upper surface of the light-emitting mesa beyond the recess of the insulating layer, the surface area of the first epitaxial layer is not limited by the aperture of the recess, so as to significantly increase the surface area and thickness of the first epitaxial layer; furthermore, due to the fact that only the light-emitting layer and the second epitaxial layer need to be accommodated inside the recess, these two layers have a greater area and thickness compared to the structure that requires accommodating three layers in the prior art, so that the area and thickness of the epitaxial layer are better increased and the light output is increased.

(3) The present disclosure also increases the metal bonding surface by coating metal at the through-hole contact portions on the hybrid bonding surface, so that the bonding strength is enhanced and conductivity is improved. Furthermore, the present disclosure also promotes the alignment of the upper and lower stacked layers by respectively arranging bonding marks in the upper and lower stacked layers, so that the bonding accuracy is improved.

### BRIEF DESCRIPTION OF THE DRAWINGS

The present disclosure is further explained below with reference to the accompanying drawings in conjunction with specific implementation methods.

FIG. 1 illustrates a schematic diagram of a hybrid bonding-based micro-LED chip according to the present disclosure.

FIG. 2 illustrates the interface metal layer between the first and second through-hole contact portions.

FIG. 3 illustrates a top view schematic diagram and a cross-sectional schematic diagram along cross-sectional line B-B of the hybrid bonding-based micro-LED chip according to the present disclosure.

FIGS. 4A-4D illustrates a process for forming the hybrid bonding-based micro-LED chip according to the present disclosure.

### DESCRIPTION OF THE EMBODIMENTS

In the following description, the present disclosure is described with reference to various embodiments. However, those skilled in the art will recognize that various embodiments can be implemented without one or more specific details or with other alternative and/or additional methods, materials, or components. In other situations, well-known structures, materials, or operations are not shown or described in detail so as not to obscure the inventive point of the present disclosure. Similarly, for the purpose of explanation, specific quantities, materials, and configurations are set forth in order to provide a comprehensive understanding of embodiments of the present disclosure. However, the present disclosure is not limited to these particular details.

It should be noted that various components in the accompanying drawings may be exaggerated for the purpose of illustrative illustration and are not necessarily true to scale. In the accompanying drawings, components that are identical or functionally identical are provided with the same accompanying drawing reference signs.

In the present disclosure, unless otherwise specified, the words "arranged on", "arranged above" and "arranged over" do not exclude the existence of intermediates between the two. Furthermore, "arranged on or above" merely indicates the relative positional relationship between the two components, but under certain circumstances, such as when the product direction is reversed, it can be converted to "arranged under or below", and vice versa.

In the present disclosure, the embodiments are merely intended to illustrate the scheme of the present disclosure and should not be construed as limiting.

In the present disclosure, the quantifiers "a" and "one" do not exclude scenarios with a plurality of elements, unless otherwise specified.

In the present disclosure, the term "connect" may refer to either the two being directly connected or the two being indirectly connected through an intermediate component.

In the present disclosure, the term "configure" refers to the setting of the shape, structure, material, and/or function of a target object to achieve a desired technical effect, wherein "configure" includes various alternative technical means to achieve this technical effect, these technical means become apparent under the teachings of the present disclosure.

In the present description, a reference to "an embodiment" or "the embodiment" means that particular feature, structure or characteristic described in connection with the embodiment are included in at least one embodiment of the present disclosure. The phrase "in one embodiment" appearing throughout this description may not necessarily all refer to the same embodiment.

It should be noted that the embodiments of the present disclosure describe the process steps in a specific order, however, this is only for the purpose of illustrating the specific embodiment, rather than limiting the order of the steps. On the contrary, in different embodiments of the present disclosure, the order of the steps can be modified according to the adjustment of the process.

In the present disclosure, the term "upper portion of the light-emitting mesa" refers to the portion of the light-emitting mesa facing the microlens or light extraction side, while the term "lower portion of the light-emitting mesa" refers to the portion of the light-emitting mesa facing the drive backplane or anode. Similarly, the term "upper surface or top surface of the light-emitting mesa" refers to the surface of the light-emitting mesa facing the microlens or light extraction side, while the term "lower surface or bottom surface of the light-emitting mesa" refers to the surface of the light-emitting mesa facing the drive backplane or anode.

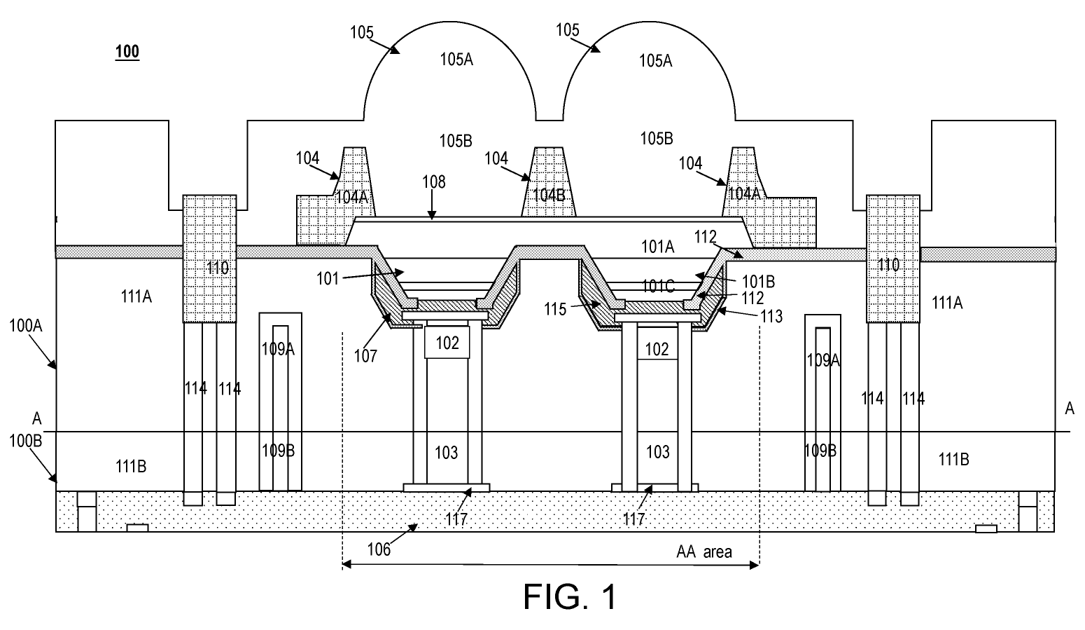

FIG. 1 illustrates a schematic diagram of a hybrid bonding-based micro-LED chip 100 according to the present disclosure.

As shown in FIG. 1, the hybrid bonding-based micro-LED chip 100 of the present disclosure includes an upper stacked layer 100A and a lower stacked layer 100B, wherein the upper stacked layer 100A and the lower stacked layer 100B are formed into a complete micro-LED chip 100 through hybrid bonding at interface A. The structure and components of the upper stacked layer 100A and the lower stacked layer 100B are described in detail below.

### Upper stacked layer

The upper stacked layer 100A includes a first insulating layer 111A, a light-emitting mesa 101, a transparent conductive layer 108, a first electrode 104 (cathode), a first through-hole contact portion 102, a second electrode 110 (anode), a first bonding mark 109A, and microlens 105. The various components are described below, respectively.

The first insulating layer 111A is configured to accommodate at least a part of the light-emitting mesa 101 and provide electrical insulation for it. Herein, the first insulating layer 111A has a recess 107 configured to accommodate the light-emitting layer and the second epitaxial layer of the light-emitting mesa 101, as well as the ancillary structures. For a detailed description of the light-emitting mesa 101 and its ancillary structures (such as the passivation layer, the reflective mirror layer, etc.), reference may be made to the light-emitting mesa 101 and description thereof. Herein, it should be noted that the recess 107 may be formed after the light-emitting mesa 101, i.e., the light-emitting mesa 101 and its ancillary structures are first formed on a temporary substrate, then the first insulating layer 111A surrounding them is formed on the light-emitting mesa and its ancillary structures. The material of the first insulating layer 111A may be, for example, silicon dioxide, silicon nitride, high-k dielectric materials (such as hafnium oxide, aluminum oxide, etc.), and so on. Methods for forming the first insulating layer 111A may include thermal oxidation, chemical vapor deposition (CVD), etc. The thickness of the first insulating layer 111A is, for example, 1 to 3 μm, preferably 2 μm, and more preferably 0.6 to 1.4 μm. Furthermore, the first insulating layer 111A may be planarized at interface A (e.g., through chemical mechanical polishing CMP) to facilitate hybrid bonding with the second insulating layer 111B.

The light-emitting mesa 101 is configured to emit light, wherein the top surface area of the light-emitting mesa 101 is greater than the bottom surface area of the light-emitting mesa 101. The light-emitting mesa 101 includes a first epitaxial layer 101A, a light-emitting layer 101B, and a second epitaxial layer 101C, wherein the first epitaxial layer 101A is arranged on the top of the light-emitting mesa, i.e., the side facing the light extraction surface; the light-emitting layer 101B is arranged in the recess 107 and arranged between the first epitaxial layer 101A and the second epitaxial layer 101C; and the second epitaxial layer 101C is arranged on the bottom of the light-emitting mesa 101, i.e., the side facing the drive circuit 106. The light-emitting layer 101B may include, for example, a multi-quantum-well layer and an electron barrier layer. In one embodiment of the present disclosure, the first epitaxial layer 101A is an N-type GaN layer or an N-type AlGaN layer, and the second epitaxial layer 101C is a P-type GaN layer or a P-type AlGaN layer, i.e., the material of the second epitaxial layer 101C is a material layer of a second conductivity type including at least two or more elements of Ga, N, As, Al, In, and P, and the first epitaxial layer 101A is a material layer of a first conductivity type including at least two or more elements of Ga, N, As, Al, In, and P. The multi-quantum-well layer is an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present disclosure, the first epitaxial layer may also be a P-type GaN layer or a P-type AlGaN layer, and the second epitaxial layer is an N-type GaN layer or an N-type AlGaN layer. The top width of the light-emitting mesa 101 is, for example, 0.5 to 3 μm, preferably 1.0 to 2.0 μm. The thickness of the first epitaxial layer 101A is, for example, 4000 to 5000 angstroms, the thickness of the light-emitting layer 101B is, for example, 3500 to 4000 angstroms, and the thickness of the second epitaxial layer 101C is, for example, 2500 to 3500 angstroms. 1 angstrom = 10^(-10) meters. From FIG. 1, it can be seen that the first epitaxial layer 101A is located outside the recess 107, while the light-emitting layer 101B and the second epitaxial layer 101C are located within the recess 107, therefore, the surface area of the first epitaxial layer 101A is not limited by the aperture area of the recess 107 but can be significantly greater than the aperture area of the recess 107, thereby significantly increasing the area and thickness of the first epitaxial layer 101A; furthermore, due to the fact that merely the light-emitting layer 101B and the second epitaxial layer 101C need to be accommodated in the recess 107, these two layers have a larger area and thickness compared to the structure that requires accommodating three layers in the prior art, and thus the area and thickness of the epitaxial layer 101 are better increased, and the light output is improved. It can also be seen herein that the first epitaxial layer 101A passes through the first electrode 104 (herein is the cathode) from below the first electrode 104, so that the first epitaxial layers 101A of adjacent light-emitting mesas 101 can be connected to each other, and thus in the case of a common-cathode structure (i.e., where the first epitaxial layers of all micro-LEDs in the same array are connected to a common cathode), compared to the case where it is connected to the cathode 104 solely by the transparent conductive layer 108 covering it, the conductivity between the cathode 104 and the first epitaxial layer 101A can be significantly enhanced, thereby increasing its power supply. Furthermore, the contact cross-section between the first epitaxial layer 101A and the cathode 104 at the edge is partially planar and partially inclined surface. The inclined surface increases the contact area between the first epitaxial layer 101A and the cathode 104 compared to a vertical surface, and thus the conductivity is increased.

The light-emitting mesa 101 also includes ancillary structures such as passivation layers 112 and 113, a reflective mirror layer 115, etc. The passivation layer 112 is arranged between the light-emitting mesa 101 and the reflective mirror layer 115, and optionally extends on the upper surface of the first insulating layer 111A, and the passivation layer 113 is arranged between the inner wall of the recess 107 and the reflective mirror layer 115, and optionally extends on the upper surface of the first insulating layer 111A. In another embodiment, merely one of the passivation layers 112 and 113 extends on the upper surface of the first insulating layer 111A, or neither does not extend on the upper surface of the first insulating layer 111A, instead, they extend merely until the upper surface of the first insulating layer 111A, while the upper surface of the first insulating layer 111A is covered by another insulating layer or dielectric layer. The function of passivation layers 112 and 113 is not only to reduce current leakage at the sidewalls, but also to passivate sidewall defects and block damage to the light-emitting mesa caused by water, oxygen, etc., during operation, they can also prevent metal diffusion from the reflective mirror layer 115, the cathode 104 etc. to the first insulating layer 111 or the light-emitting mesa 101. The passivation layers 112 and 113 may be formed by depositing SiO₂ material using a CVD process, and also may be formed by depositing Al₂O₃ material using an ALD process. The reflective mirror layer 115 is configured to reflect light from the light-emitting mesa 101 upward. For this purpose, the reflective mirror layer 115 has an inclined surface on the side facing the light-emitting mesa 101. The material of the reflective mirror layer 115 is, for example, silver, or a combination of a plurality of metal layers such as nickel, silver, platinum, etc., and its thickness is 2000 to 4000 angstroms, preferably 3000 to 3500 angstroms. The reflective mirror layer 115 can be formed, for example, by methods such as evaporation, sputtering, or chemical vapor deposition (CVD), etc. The thickness of the passivation layer 112 between the reflective mirror layer 112 and the light-emitting mesa 101 is 800 to 2000 angstroms, preferably 1000 to 1600 angstroms. The thickness of the passivation layer 113 between the reflective mirror layer 115 and the inner wall 107 of the recess is 200 to 800 angstroms, preferably 300 to 600 angstroms.

The transparent conductive layer 108 is arranged on the first epitaxial layer 101A and electrically connects the first electrode 104 (cathode) with the first epitaxial layer 101A. Herein, the transparent conductive layer 108 extends on the first epitaxial layer 101A and fully covers the first epitaxial layer 101A, thereby providing more uniform power supply for the first epitaxial layer 101A. In other embodiments, the transparent conductive layer 108 may merely partially cover the first epitaxial layer 101A. Furthermore, the transparent conductive layer 108 extends below the first electrode 104, which is the cathode in this case, such that the transparent conductive layer 108 extends continuously on the first epitaxial layer 101A of adjacent light-emitting mesas 101, so that the coverage area for the first epitaxial layer 101A is increased. The material of the transparent conductive layer 108 is, for example, metal oxide such as indium tin oxide ITO or zinc oxide ZnO, etc.; its formation methods, for example, include physical vapor deposition (PVD), chemical vapor deposition (CVD), sol-gel method, solution coating method, etc.

The first electrode 104, which herein is the cathode, is arranged to surround the light-emitting mesa 101. The cathode 104 and its connecting components may be made of materials such as metals (such as silver, gold, or platinum), graphene, ITO, aluminum doped zinc oxide (AZO) or fluorine doped tin oxide (FTO), or any combination of the above materials. In yet another embodiment of the present disclosure, the cathode 104 and its connecting components may be made of non-transparent or transparent conductive materials, such as indium tin oxide (ITO). In a preferred embodiment, the cathode 104 is made of a reflective metal (such as copper, silver or aluminum), so that the cathode 104 can optically isolate adjacent light-emitting mesas 101 from each other and meanwhile also can reflect light from the light-emitting mesas 101, for example, reflect the light upward to the microlens 105, thereby increasing light output. In another embodiment, a reflective layer, such as a silver layer, may be coated onto the surface of the cathode 104 to provide reflective capability. Herein, the surface of the cathode 104 facing the light-emitting mesa 101A is an inclined surface, and it is inclined toward two sides (i.e. inclined from the bottom surface toward two sides), so that the light falling on it can be reflected upward, i.e. toward the light extraction side. Furthermore, the cathode 104 may be divided into an edge cathode 104A and a central cathode 104B, wherein the edge cathode 104A is arranged between the second electrode 110 (herein is the anode) and the outermost light-emitting mesa 101, wherein a part of the edge cathode 104A is arranged on the passivation layer 112, and another portion is arranged on the transparent conductive layer 108, while the central cathode 104B is arranged between adjacent light-emitting mesas 101, wherein the central cathode 104B is arranged on the transparent conductive layer 108. In this way, the edge cathode 104A can completely cover the side surface of the first epitaxial layer 101A and be in electrical contact with it, thereby increasing the electrical contact area between the cathode 104 and the first epitaxial layer 101A.

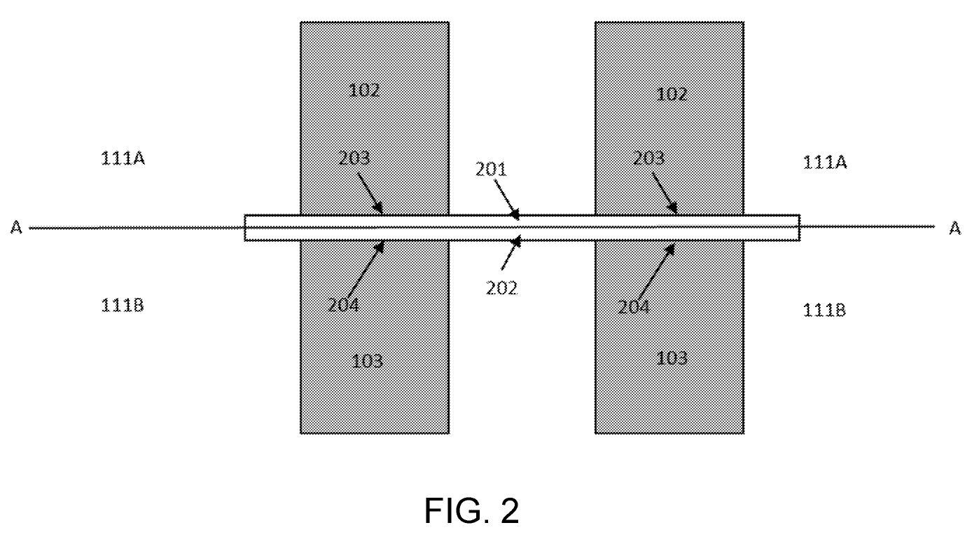

The first through-hole contact portion 102 is electrically connected with the bottom of the light-emitting mesa 101 and passes through the first insulating layer 111A. The first through-hole contact portion 102 is used for hybrid bonding with the second through-hole contact portion 103, and thus electrically connects the bottom of the light-emitting mesa 101, particularly the second epitaxial layer 101C to the second electrode 110 (herein it is the anode). The first through-hole contact portion 102 is preferably a cylindrical through-hole, and the inner wall and/or central space is filled with a conductor, such as metallic copper. The diameter of the first through-hole contact portion 102 is of 0.3 to 2 μm, preferably 0.6 to 1.4 μm. The first through-hole contact portion 102 may be planarized at interface A (e.g., through chemical mechanical polishing (CMP)) to facilitate hybrid bonding with the second through-hole contact portion 103. Furthermore, referring to FIG. 2, in order to enhance the bonding strength and improve the conductivity between the first through-hole contact portion 102 and the second through-hole contact portion 103, a first interface metal layer 201 may be arranged at the first aperture 203 of the first through-hole contact portion 102, and the area of the first interface metal layer 201 is greater than the area of the first aperture 203. Similarly, a second interface metal layer 202 may be arranged at the second aperture 204 of the second through-hole contact portion 103, and the area of the second interface metal layer 202 is greater than the area of the second aperture 204. The areas of the first interface metal layer 201 and the second interface metal layer 202 may be equal, or the area of the first interface metal layer 201 may be greater or less than the area of the second interface metal layer 202. After the first interface metal layer 201 and the second interface metal layer 202 are bonded to each other, the formed bonding surface is greater than the bonding surface formed by directly bonding the first aperture of the first through-hole contact portion 102 and the second aperture 204 of the second through-hole contact portion 103, and thus the bonding strength is enhanced and the conductivity between the first through-hole contact portion 102 and the second through-hole contact portion 103 is improved. The first interface metal layer 201 and the second interface metal layer 202 are made of, for example, a conductive metal such as copper. Their formation methods may include, for example, physical vapor deposition (PVD), chemical vapor deposition (CVD), electroplating, chemical plating, and so on. The formation method of the first through-hole contact portion 102 may be, for example, as follows: a light-emitting mesa 101 and a first insulating layer 111A are formed on a temporary substrate, then the first insulating layer 111A is etched to form through-holes leading to the bottom of the light-emitting mesa 101, subsequently, a metal is deposited in the through-holes, and finally the apertures of the through-holes are planarized to form the bonding surface.

The second electrode 110, which herein is the anode, is electrically connected with the drive circuit 106 through a third through-hole contact portion 114 passing through the first insulation layer 111A and the second insulation layer 111B. The anode 110 may be, for example, connected to an external power source or control source for supplying power for the micro-LED chip 100 or controlling the micro-LED chip 100. Herein, the third through-hole contact portion 114 may include a plurality of through-hole contact portions for connecting the second epitaxial layers 101C of a plurality of light-emitting mesas to the anode 110. Herein, it is exemplarily shown that the third through-hole contact portion 114 includes two through-hole contact portions, but this is merely an example, and other numbers of through-hole contact portions 114 are also conceivable. The third through-hole contact portion 114 may be formed either before hybrid bonding or after hybrid bonding. If the third through-hole contact portion 114 is formed before hybrid bonding, then the upper and lower portions of the third through-hole contact portion 114 are first formed in the upper stacked layer 100A and the lower stacked layer 100B, respectively, then after hybrid bonding, these two portions are interconnected to form the third through-hole contact portion, and then the first insulating layer 111A is etched from above to form the anode 110 on the third through-hole contact portion 114. If the third through-hole contact portion 114 is formed after hybrid bonding, then the first insulating layer 111A is etched from above to form through-holes leading to the drive circuit 106, metal is then deposited in the through-holes, then the third through-hole contact portion 114 is etched to form a recess, metal is then deposited in the recess to form the anode 110. The anode 110 and its connecting components may be made of materials such as metals (e.g., copper, silver, or aluminum), graphene, ITO, aluminum doped zinc oxide (AZO), or fluorine doped tin oxide (FTO), or any combination of the above materials.

The first bonding mark 109A is arranged in the first insulating layer 111A and exposes the first marking surface, i.e., the aperture of the first bonding mark. The function of the first bonding mark 109A in the upper stacked layer 100A is to serve as a mark aligned with the second bonding mark 109B in the lower stacked layer 100B, and thus precise hybrid bonding is achieved, wherein the second bonding mark 109B is arranged in the second insulating layer 100B and exposes the second marking surface, i.e., the aperture of the second bonding mark. The alignment method of the first bonding mark 109A with the second bonding mark 109B is to align and adhere the first marking surface with the second marking surface during hybrid bonding, at this time, the upper stacked layer 100A and the lower stacked layer 100B have been aligned, and then hybrid bonding can be performed. The first bonding mark 109A and the second bonding mark 109B may be metal through-holes, and the two may be bonded at the interface. Furthermore, the first bonding mark 109A and the second bonding mark 109B may have enlarged apertures and/or the apertures may be coated with a metal layer to facilitate identification of their positions and enhance bonding strength.

The microlens 105 is arranged above the light-emitting mesa 101 for shaping such as focusing or collimating the light emitted therefrom. The microlens includes a lens portion 105A and a spacer portion 105B. The lens portion 105A is arranged at the outermost side, i.e., the topmost and configured to shape light from the light-emitting mesa 101. The spacer portion 105B is arranged between the lens portion 105A and the light-emitting mesa 101 to adjust the focal position of the lens portion 105A, for example, parameters such as the thickness of the spacer portion 105B and the curvature of the lens portion 105A, etc. are adjusted, such that the focal point of the lens portion 105A is precisely located in the light-emitting mesa 101 of the micro-LED. The width of the microlens 105 is, for example, 0.8 to 4 μm, preferably 1 to 3 μm. The distance between the lens portion 105A and the cathode 104 is, for example, 0.05 to 4 μm, preferably 0.1 to 0.3 μm. The microlens 105 corresponds one-to-one with the light-emitting mesa 101. Meanwhile, in the present embodiment, adjacent microlenses 105 have gaps between them and their bottoms are connected with each other. The bottoms of the gaps are higher than the top of the light-emitting mesa 101 or higher than the bottom of the light-emitting layer 101B of the light-emitting mesa 101, and the lens portion 104A is located above the cathode 104. The microlens 105 may be formed through a plurality of deposition steps, and during the formation process of the microlens, a SiO₂ film layer is first deposited, then ion etching is performed, and the microlens is formed at positions on the surface of the transparent conductive layer 108 corresponding to each light-emitting mesa 101.

### Lower stacked layer

The lower stacked layer 100B includes a second insulating layer 111B, a second through-hole contact portion 103, a drive backplane 106, and a second bonding mark 109B. The various components are described below, respectively.

The second insulating layer 111B is arranged on the drive backplane 106 and is configured to accommodate the second through-hole contact portion 103. The material of the second insulating layer 111B may be, for example, silicon dioxide, silicon nitride, high-k dielectric materials (e.g., hafnium oxide, aluminum oxide, etc.), and so on. The second insulating layer 111B may be, for example, formed on the drive backplane 106 through methods such as thermal oxidation or chemical vapor deposition (CVD), etc. The thickness of the second insulating layer 111B may be, for example, 1 to 3 μm, preferably 2 μm, and more preferably 0.6 to 1.4 μm. Furthermore, the second insulating layer 111B may be planarized at interface A (e.g., through chemical mechanical polishing (CMP)) to facilitate hybrid bonding with the first insulating layer 111A.

The second through-hole contact portion 103 passes through the second insulating layer 111B. The second through-hole contact portion 103 is configured to hybrid bond with the first through-hole contact portion 102 at interface A, and thus electrically connect the bottom of the light-emitting mesa 101, particularly the second epitaxial layer 101C to the second electrode 110 (herein it is the anode). The second through-hole contact portion 103 is preferably a cylindrical through-hole, and the inner wall and/or central space is filled with a conductor, such as metallic copper. The diameter of the second through-hole contact portion 103 is of 0.5 to 2.2 μm, preferably 0.8 to 1.6 μm. The second through-hole contact portion 103 may be planarized at interface A (e.g., through chemical mechanical polishing CMP) to facilitate hybrid bonding with the first through-hole contact portion 102. Furthermore, referring to FIG. 2, in order to enhance the bonding strength and improve the conductivity between the second through-hole contact portion 103 and the first through-hole contact portion 102, a second interface metal layer 202 may be arranged at the second aperture 204 of the second through-hole contact portion 103, and the area of the second interface metal layer 202 is greater than the area of the second aperture 204. Similarly, a first interface metal layer 201 may be arranged at the first aperture 203 of the first through-hole contact portion 102, and the area of the first interface metal layer 201 is greater than the area of the first aperture 203. The areas of the first interface metal layer 201 and the second interface metal layer 202 may be equal, or the area of the first interface metal layer 201 may be greater or less than the area of the second interface metal layer 202. After the first interface metal layer 201 and the second interface metal layer 202 are bonded to each other, the formed bonding surface is greater than the bonding surface formed by directly bonding the first aperture of the first through-hole contact portion 102 and the second aperture 204 of the second through-hole contact portion 103, and thus the bonding strength is enhanced and the conductivity between the first through-hole contact portion 102 and the second through-hole contact portion 103 is improved. The first interface metal layer 201 and the second interface metal layer 202 are made of, for example, a conductive metal such as copper. Their formation methods may include, for example, physical vapor deposition (PVD), chemical vapor deposition (CVD), electroplating, chemical plating, and so on. The formation method of the second through-hole contact portion 103 may be, for example, as follows: a drive backplane 106 is provided, then a second insulating layer 111B is formed on the drive backplane 106, then the second insulating layer 111B is etched to form through-holes leading to the top of the drive backplane 106, subsequently, a metal is deposited in the through-holes, and finally the apertures of the through-holes are planarized to form the bonding surface.

The drive backplane 106 is electrically connected with the second through-hole contact portion 103 to electrically connect the second epitaxial layer 101C of the light-emitting mesa 101 to the anode 110. For this purpose, the drive backplane 106 has conductive line layers for interconnecting each second through-hole contact portion 103 to the corresponding anode 110. The drive backplane 106 may be, for example, a thin-film transistor TFT drive circuit and may include 2T1C drive circuit, 3T1C drive circuit, and 5T2C drive circuit. The drive backplane 106 is configured to drive the micro-LEDs, such as controlling the switching on/off and brightness of the micro-LEDs. The drive backplane 106 may include, for example, transistors, capacitors, a conductive line layer, an insulating layer, and a metal layer, etc. The conductive line layer is formed on the substrate and configured to supply power to the micro-LED array. The insulating layer is formed on the conductive line layer, wherein through-holes are arranged in the insulating layer, and through-hole contact portions (e.g., IC copper pillars) are arranged in the through-holes for electrically connecting the conductive line layer with the micro-LED array. The metal layer is used for bonding and electrically contacting the micro-LEDs. The conductive line layer, the metal layer, and the insulating layer may be formed on substrate through deposition methods such as physical vapor deposition (PVD) and chemical vapor deposition (CVD).

The second bonding mark 109B is arranged in the second insulating layer 111B and exposes the second marking surface, i.e., the aperture of the second bonding mark. The function of the second bonding mark 109B in the lower stacked layer 100B is to serve as a mark aligned with the first bonding mark 109A in the upper stacked layer 100A, and thus precise hybrid bonding is achieved. The alignment method of the first bonding mark 109A with the second bonding mark 109B is to align and adhere the first marking surface with the second marking surface during hybrid bonding, at this time, the upper stacked layer 100A and the lower stacked layer 100B have been aligned, and then hybrid bonding can be performed. The first bonding mark 109A and the second bonding mark 109B may be metal through-holes, and the two may be bonded at the interface. Furthermore, the first bonding mark 109A and the second bonding mark 109B may have enlarged apertures and/or the apertures may be coated with a metal layer to facilitate identification of their positions and enhance bonding strength.

After the formation of the lower stacked layer 100A and the upper stacked layer 100B, the lower stacked layer 100A is jointed with the upper stacked layer 100B through hybrid bonding, such that the first through-hole contact portion 102 is bonded with the second through-hole contact portion 103 and the first insulating layer 111A is bonded with the second insulating layer 111B, and optionally the first bonding mark 109A is bonded with the second bonding mark 109B, and the upper and lower portions of the third through-hole contact portion 114 are bonded with each other. The present disclosure solves the technical problem encountered in manufacturing upside-down arranged trapezoidal light-emitting mesa with a large upper surface and a small lower surface, i.e., the problem of electrical connection of the light-emitting mesa to the driving circuit, by respectively fabricating the upper stacked layer 100A and the lower stacked layer 100B and then jointing them with each other through hybrid bonding. The present disclosure achieves electrical connection of the light-emitting mesa 101 to the drive circuit 106 through hybrid bonding, allowing both the upper stacked layer 100A and the lower stacked layer 100B to be manufactured from the surface opposed to the hybrid bonding surface, i.e., interface A, towards the hybrid bonding surface, so that high-quality conductive structures, such as the first to third through-hole contact portions (such as IC copper pillars) are achieved, and the length of the conductive structure can also be flexibly selected.

An example of the hybrid bonding may include the following two parts:

(1) Dielectric-to-dielectric bonding (i.e., bonding between the first insulating layer 111A and the second insulating layer 111B): at room temperature, extremely flat and smooth dielectric surfaces obtained through chemical mechanical polishing (CMP) are brought into close contact at room temperature after activation through methods such as plasma treatment to achieve preliminary bonding.

(2) Metal-to-metal bonding (i.e., bonding between through-hole contact portions): after completing the dielectric-to-dielectric bonding, the upper and lower stacked layers are heated to 200-400°C for annealing treatment to strengthen the dielectric bonding and facilitate metal-to-metal bonding, thereby achieving hybrid bonding.

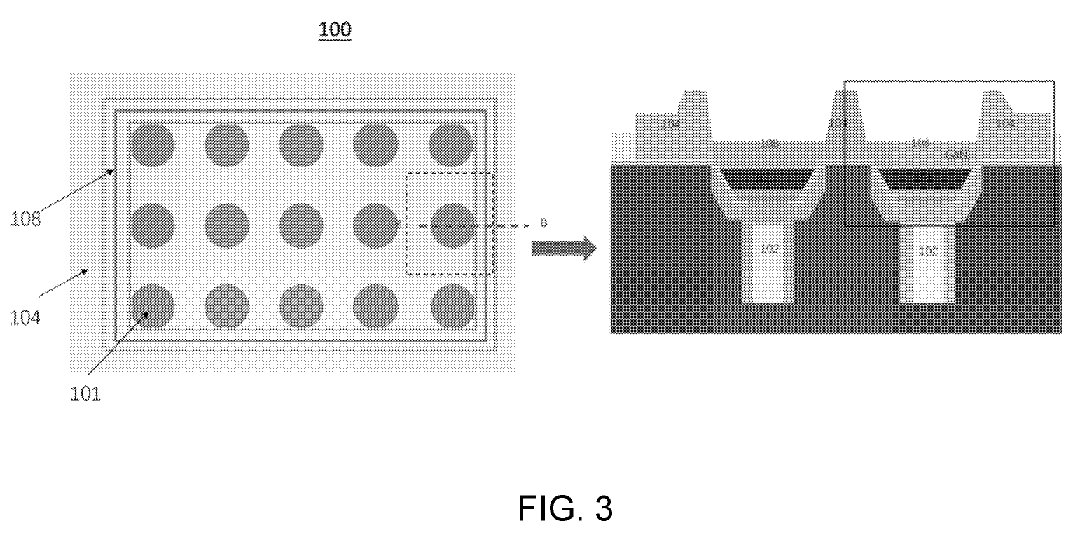

FIG. 3 illustrates a top view schematic diagram and a cross-sectional schematic diagram along cross-sectional line B-B of the hybrid bonding-based micro-LED chip according to the present disclosure, wherein the left part of FIG. 3 illustrates the top view schematic diagram of the hybrid bonding-based micro-LED chip 100, and the right part illustrates the cross-sectional schematic diagram along cross-sectional line B-B of the hybrid bonding-based micro-LED chip.

As shown on the left side of FIG. 3, the hybrid bonding-based micro-LED chip 100 includes a plurality of light-emitting mesas 101. The light-emitting mesa 101 has a circular light-emitting mesa, but this is only exemplary, light-emitting mesas of other shapes are also conceivable. The cathode 104 is arranged to surround the light-emitting mesa 101, and the transparent conductive layer 108 is arranged below the cathode 104 and partially exposed at some positions. As shown in FIG. 2, the light-emitting mesa 101 of the hybrid bonding-based micro-LED chip 100 has an upper surface larger than the lower surface, and the bottom has a first through-hole contact portion 102 electrically connected with the drive backplane.

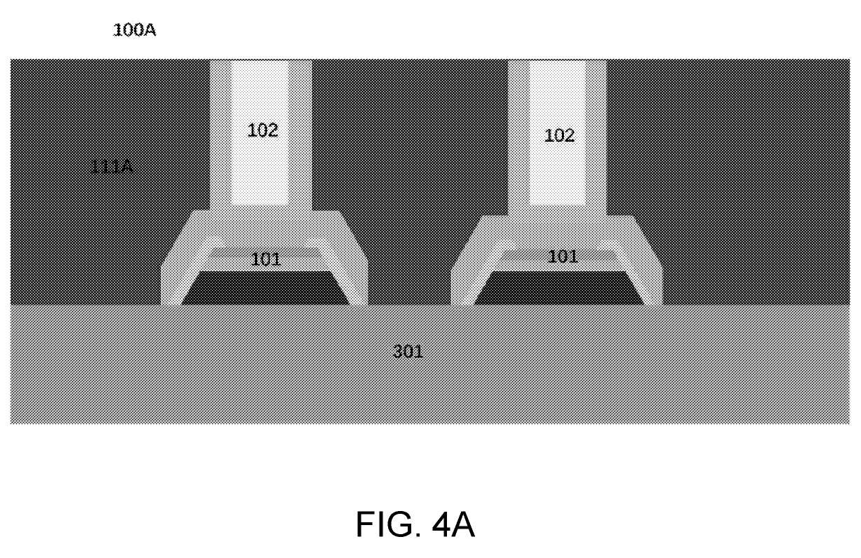

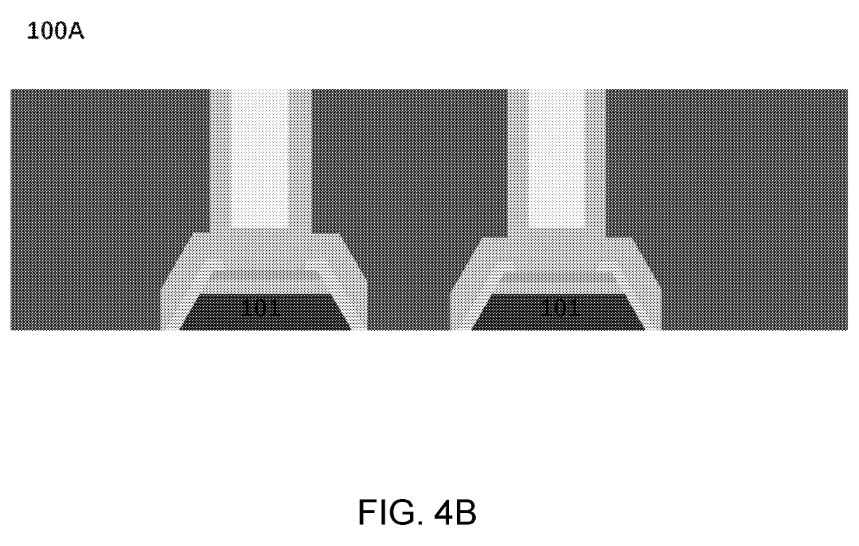

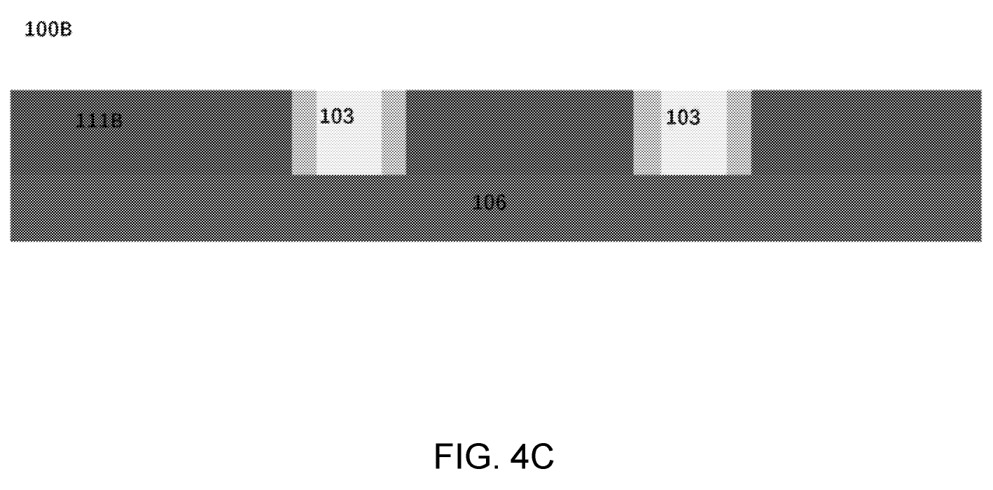

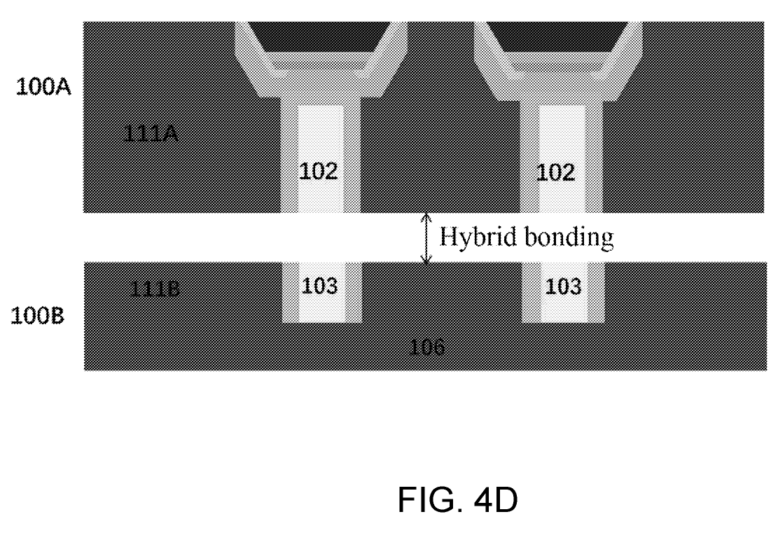

The method for manufacturing the micro-LED chip according to the disclosure is described below in conjunction with FIGS. 4A to 4D.

In step S1, as shown in FIG. 4A, a temporary substrate 301 is provided, and a part of the upper stacked layer 100A is formed on the temporary substrate 301, the part includes:

Firstly, a light-emitting layer, a second epitaxial layer of the light-emitting mesa 101 is deposited on the temporary substrate 301.

Then, a passivation layer is deposited on the light-emitting mesa.

Next, a first insulating layer 111A is deposited on the light-emitting mesa.

Then, a first through-hole contact portion 102 is etched in the first insulating layer 111A, wherein the bottom of the first through-hole contact portion 102 exposes the bottom of the light-emitting mesa 101.

Finally, metal is deposited in the first through-hole contact portion 102.

In step S2, as shown in FIG. 4B, the upper stacked layer 100A is debonded from the temporary substrate to expose the light-emitting layer of the light-emitting mesa 101.

In step S3, as shown in FIG. 4C, the lower stacked layer 100B is formed, including:

First, a drive backplane 106 is formed.

Then, a second insulating layer 111B is deposited on the drive backplane 106.

Next, a second through-hole contact portion 103 is etched in the second insulating layer 111B, wherein the bottom of the second through-hole contact portion 103 exposes an electrical contact portion of the drive backplane 106.

Then, metal is deposited in the second through-hole contact portion 103.

In step S3, as shown in FIG. 4D, the upper stacked layer and lower stacked layer are hybrid bonded, such that the first through-hole contact portion 102 is bonded with the second through-hole contact portion 103, and the first insulating layer 111A is bonded with the second insulating layer 111B.

In step S4, other structures are formed on the hybrid bonded upper stacked layer. For example, these structures include (referring to FIG. 1):

A passivation layer 112 is deposited on the top surface of the light-emitting mesa 101.

The passivation layer 112 is etched to expose the light-emitting layer 101B of the light-emitting mesa.

A first epitaxial layer 101A is deposited on the light-emitting layer 101B. The first epitaxial layer 101A may extend beyond the recess 107 and protrude beyond the passivation layer 112 by a certain height.

A transparent conductive layer 108 is deposited on the first epitaxial layer 101A.

A cathode 104 is deposited on the transparent conductive layer 108.

A microlens 105 is deposited on the cathode 104 and the transparent conductive layer 108.

The first and second insulating layers 111A and 111B are etched at the side surface of the light-emitting mesa 101 to form a third through-hole contact portion 114, and the bottom of the third through-hole contact portion 114 exposes the electrical contact portion of the drive backplane 106.

Metal is deposited in the third through-hole contact portion 114 to form an anode 110.

Although some embodiments of the present disclosure have been described in the present application, however, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the present disclosure and thus encompass methods and structures within the scope of these claims themselves and their equivalent variations.

What is claimed is:

1. A hybrid bonding-based micro-LED chip, comprising:
an upper stacked layer comprising a first insulating layer, a light-emitting mesa and first through-hole contact portion, wherein the first insulating layer is configured to accommodate the light-emitting mesa and the first through-hole contact portion, the light-emitting mesa is configured to emit light, and the first through-hole contact portion is electrically connected with a bottom of the light-emitting mesa and configured to pass through the first insulating layer; and
a lower stacked layer comprising a second insulating layer, a second through-hole contact portion, and a drive backplane, wherein the second insulating layer is configured to accommodate the second through-hole contact portion; the second through-hole contact portion is configured to pass through the second insulating layer; and the drive backplane is electrically connected with the second through-hole contact,
wherein a top surface area of the light-emitting mesa is greater than a bottom surface area of the light-emitting mesa;
wherein the lower stacked layer is bonded with the upper stacked layer through hybrid bonding, so that the first through-hole contact is bonded with the second through-hole contact portion and the first insulating layer is bonded with the second insulating layer.

2. The micro-LED chip according to claim 1, wherein:
the upper stacked layer further comprises a first bonding mark arranged in the first insulating layer and exposing a first marking surface;
the lower stacked layer further comprises a second bonding mark arranged in the second insulating layer and exposing a second marking surface; and
wherein during hybrid bonding, the first marking surface is aligned with the second marking surface to align the upper stacked layer with the lower stacked layer.

3. The micro-LED chip according to claim 1, wherein the light-emitting mesa comprises a first epitaxial layer, a light-emitting layer and a second epitaxial layer, wherein:
the first epitaxial layer is configured to extend beyond a recess of the first insulating layer and be in electrical contact with the light-emitting layer;
the light-emitting layer is located in the recess and between the first epitaxial layer and the second epitaxial layer; and
the second epitaxial layer is located in the recess and is in electrical contact with the light-emitting layer and the first through-hole contact portion.

4. The micro-LED chip according to claim 3, wherein the upper stacked layer further comprises a transparent conductive layer, a passivation layer, a cathode and an anode, wherein
the transparent conductive layer is located on the first epitaxial layer and is configured to electrically connect a cathode with the first epitaxial layer;
the passivation layer is configured to surround a side surface of the light-emitting mesa and extend to an upper surface of the first insulating layer;
the cathode is configured to surround the light-emitting mesa; and
the anode is configured to electrically connect with the drive backplane through a third through-hole contact portion passing through the first insulating layer and the second insulating layer.

5. The micro-LED chip according to claim 4, wherein the cathode comprises:
an edge cathode located between the anode and the outermost light-emitting mesa, wherein a part of the edge cathode is on the passivation layer and another part is on the transparent conductive layer; and
a central cathode located between adjacent light-emitting mesas, wherein the central cathode is on the transparent conductive layer.

6. The micro-LED chip according to claim 4, wherein the cathode is a reflective electrode made of metal.

7. The micro-LED chip according to claim 5, wherein:
a side of the edge cathode facing the light-emitting mesa is an inclined surface; and
two sides of the central cathode facing the light-emitting mesa are inclined surfaces.

8. The micro-LED chip according to claim 5, wherein the first epitaxial layer partially passes through the edge cathode and fully passes through the central cathode, wherein an edge of the first epitaxial layer in the edge cathode is an inclined surface.

9. The micro-LED chip according to claim 4, wherein the upper stacked layer further comprises:
a reflective mirror layer located between an inner wall of the recess and the passivation layer, wherein a side of the reflective mirror layer facing the light-emitting mesa has an inclined surface to reflect light from the light-emitting mesa upward.

10. The micro-LED chip according to claim 4, wherein the upper stacked layer further comprises a microlens, the microlens comprising:
a lens portion located at an outermost and configured to shape light from the light-emitting mesa; and
a spacer portion located between the lens portion and the light-emitting mesa to adjust the focal position of the lens portion.

11. The micro-LED chip according to claim 1, wherein the first through-hole contact portion has a first aperture at a surface of the first insulating layer, wherein an interface metal layer is arranged at the first aperture, and an area of the interface metal layer is larger than an area of the first aperture; and/or
the second through-hole contact portion has a second aperture at a surface of the second insulating layer, wherein an interface metal layer is arranged at the second aperture, and the area of the interface metal layer is larger than an area of the second aperture.

12. The micro-LED chip according to claim 9, wherein the passivation layer is provided between the reflective mirror layer and the inner wall of the recess.

13. The micro-LED chip according to claim 8, wherein the first epitaxial layers of adjacent light-emitting mesas pass through the central cathode and are continuous with each other.

14. The micro-LED chip according to claim 1, wherein the first through-hole contact portion and the second through-hole contact portion are IC copper pillars, a surface of the drive backplane has a metal layer, the IC copper pillars are electrically connected with the metal layer, and each light-emitting mesa corresponds to one IC copper pillar.

15. The micro-LED chip according to claim 1, wherein:
a thickness of the first insulating layer is 0.6 to 1.4 μm; and/or
a thickness of the second insulating layer is 0.6 to 1.4 μm.

16. The micro-LED chip according to claim 1, wherein:
a diameter of the first through-hole contact portion is 0.6 to 1.4 μm; and/or
a diameter of the second through-hole contact portion is 0.8 to 1.6 μm.

17. The micro-LED chip according to claim 9, wherein:
a thickness of the passivation layer between the reflective mirror layer and the light-emitting mesa is 1000 to 1600 angstroms; and/or
a thickness of the passivation layer between the reflective mirror layer and an inner wall of the recess is 300 to 600 angstroms; and/or
a material of the reflective mirror layer comprises silver and its thickness is 3000 to 3500 angstroms.

18. The micro-LED chip according to claim 1, wherein:
a top width of the light-emitting mesa is 1.0 to 2.0 μm; and/or
a thickness of the first epitaxial layer is 4000 to 5000 angstroms; and/or
a thickness of the light-emitting layer is 3500 to 4000 angstroms; and/or
a thickness of the second epitaxial layer is 2500 to 3500 angstroms.

19. The micro-LED chip according to claim 10, wherein:
a width of the microlens is 1 to 3 μm; and/or
a distance between the lens portion and the cathode is 0.1 to 0.3 μm.

20. A method for manufacturing a micro-LED chip, comprising:
forming a part of an upper stacked layer on a temporary substrate, comprising:
depositing an emitting layer and a second epitaxial layer of a light-emitting mesa on the temporary substrate;
depositing a passivation layer on the light-emitting mesa;
depositing a first insulating layer on the light-emitting mesa;
etching a first through-hole contact portion on the first insulating layer, wherein a bottom of the first through-hole contact portion exposes a bottom of the light-emitting mesa;
depositing metal in the first through-hole contact portion; and
debonding the upper stacked layer from the temporary substrate;
forming a lower stacked layer, comprising:
forming a drive backplane;
depositing a second insulating layer on the drive backplane;
etching a second through-hole contact portion on the second insulating layer, wherein a bottom of the second through-hole contact portion exposes an electrical contact portion of the drive backplane; and
depositing metal in the second through-hole contact portion; and
hybrid bonding the upper stacked layer and the lower stacked layer, so that the first through-hole contact portion is bonded with the second through-hole contact portion and the first insulating layer is bonded with the second insulating layer.
